(19) United States
(12) Patent Application Publication
(10) Pub. No.: US 2009/0009956 A1
(43) Pub. Date: Jan. 8, 2009

(54) CASE OF ELECTRONIC DEVICE AND INTERFACE CARD RETAINING ASSEMBLY THEREOF

(75) Inventor: Quie-Wau CHEN, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: INVENTEC CORPORATION, Taipei (TW)

(21) Appl. No.: 11/772,888

(22) Filed: Jul. 3, 2007

(51) Int. Cl. G06F 1/16; H05K 1/18

(52) U.S. Cl. 361/686; 361/761

(57) ABSTRACT

A case of an electronic device and an interface card retaining assembly thereof are used for retaining interface cards in the case. A circuit board is disposed in the case, and the circuit board has at least one expansion slot. The interface card retaining assembly includes an interface card cradle and a functional expansion card. The interface card cradle is pivoted to the case, for swinging relative to the case. The functional expansion card is mounted to the interface card cradle, and when the interface card cradle leans against the circuit board, the functional expansion card is inserted into the expansion slot of the circuit board, so as to electrically connect to the circuit board.

### BACKGROUND OF THE INVENTION

1. Field of the Invention

The present invention relates to a case of an electronic device and an interface card retaining assembly. More particularly, the present invention relates to a case of an electronic device, in which an interface card cradle is pivoted to the case.

2. Related Art

Recently, as continuous and rapid development of science and technology, computers have become prevailing electronic devices. On the recent market, as for the desktop computers, notebook computers, or servers, the used computer peripheral hardware of the computers, for example, a peripheral component interconnect card (PCI card), has to be electrically connected to the computers, such that the computers and the computer peripheral hardware communicate and transfer signals with each other, so as to perform the preset functions of the peripheral hardware. In an ordinary computer, usually several interface cards are electrically connected to the motherboard of the computer, for increasing and expanding the functions of the computer. The interface cards are, for example, VGA cards, sound cards, network cards, USB cards, and storage device controller card, etc.

Currently, as for installing a interface card within the case of the computer server, an interface card cradle is disposed in the case, and an a raiser card with a plurality of slots is fixed in the interface card cradle is mounted to the cradle. One or more interface card are retained in the interface card cradle, and is electrically connected to each slot of the raiser card. Then, the interface card cradle is fixed at a predetermined position inside the case by screws, and the raiser card is electrically connected to the motherboard, so as to electrically connect the interface card to the motherboard. The interface cards are parallel to the motherboard and the base plate of the case, thereby solving the problem that the height of the interface card is relative larger than that in the case of a low profile server, such as 1U server. The interface card cradle has to be fixed to case by using fixing elements, for example, snapping members, hooking members, and screws. For example, in the interface card cradle disclosed in U.S. Pat. No. 6,373,691, the interface cards are retained in the interface card cradle and electrically connected to each interface card slot of the raiser card mounted to the interface card cradle. The interface card cradle is fixed at a predetermined position within the case through screws, and the raiser card is made to be electrically connected to the motherboard. Thus, the interface cards are electrically connected to the motherboard through the motherboard. However, during assembling or disassembling the interface card, it takes much time to tighten or loose the screws. As a result, the process of assembling or disassembling the interface card takes too much time. Meanwhile, the screws might easily drop on the motherboard, which results in the problem of short circuit to make the motherboard be burnt out. In addition, in the above design, when assembling or disassembling the interface card, the whole interface card cradle has to be taken away from the case, and a temporarily working table is required to place the interface card cradle for assembling or disassembling the interface card, which causes another inconvenient in using.

### SUMMARY OF THE INVENTION

In view of the above problems, the object of the present invention is to provide a case of an electronic device and an interface card retaining assembly, for reducing the number of fixing elements required for fixing the interface card cradle, in which the interface card cradle is maintained to be connected to the case during the process of assembling and disassembling the interface card, so that a temporarily working table to place the interface card cradle is not required anymore.

In order to achieve the above object, a case of an electronic device and an interface card retaining assembly are provided in the present invention. A circuit board is disposed in the case, and the circuit board has at least one expansion slot. The interface card retaining assembly includes an interface card cradle and a functional expansion card. The interface card cradle is pivoted to the case, for swinging relative to the case. The functional expansion card is mounted to the interface card cradle. When the interface card cradle leans against the circuit board, the functional expansion card is inserted in the expansion slot of the circuit board, so as to be electrically connected to the circuit board.

One of the advantages of the present invention is that the interface card cradle is pivoted to the case, so as to reduce the number of fixing members required for fixing the interface card cradle and to simplify the fixing procedure. Another advantage of the present invention is that the interface card cradle is pivoted to the case, and when the interface card cradle leans against the circuit board, the functional expansion card (for example, raiser card and interface card) is made to be directly inserted into the expansion slot, so as to simplify the steps for aligning the functional expansion card in the interface card cradle and to the expansion slots of the circuit board. Yet another advantage is that in the process of assembling and disassembling the functional expansion card, since the interface card cradle is pivoted to the case, the interface card cradle is made to temporarily stand on one side of the case, which is convenient for placing the interface card cradle.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is an exploded view of a case of an electronic device according to a first embodiment of the present invention;

FIG. 2A is a perspective view of the case of the electronic device according to the first embodiment of the present invention;

FIG. 2B is a partial enlarged view of the case of the electronic device according to the first embodiment of the present invention;

FIG. 2C is a schematic view of exploded steps for the case of the electronic device according to the first embodiment of the present invention;

FIG. 3 is another perspective view of the case of the electronic device according to the first embodiment of the present invention, showing steps for fixing the interface card cradle to the case by using a thumb screw; and

FIG. 4 is a perspective view of a case of an electronic device according to a second embodiment of the present invention.

### DETAILED DESCRIPTION OF THE INVENTION

To further understand the objective, construction, feature, and functions of the present invention, the present invention is further illustrated below in detail through the embodiments.

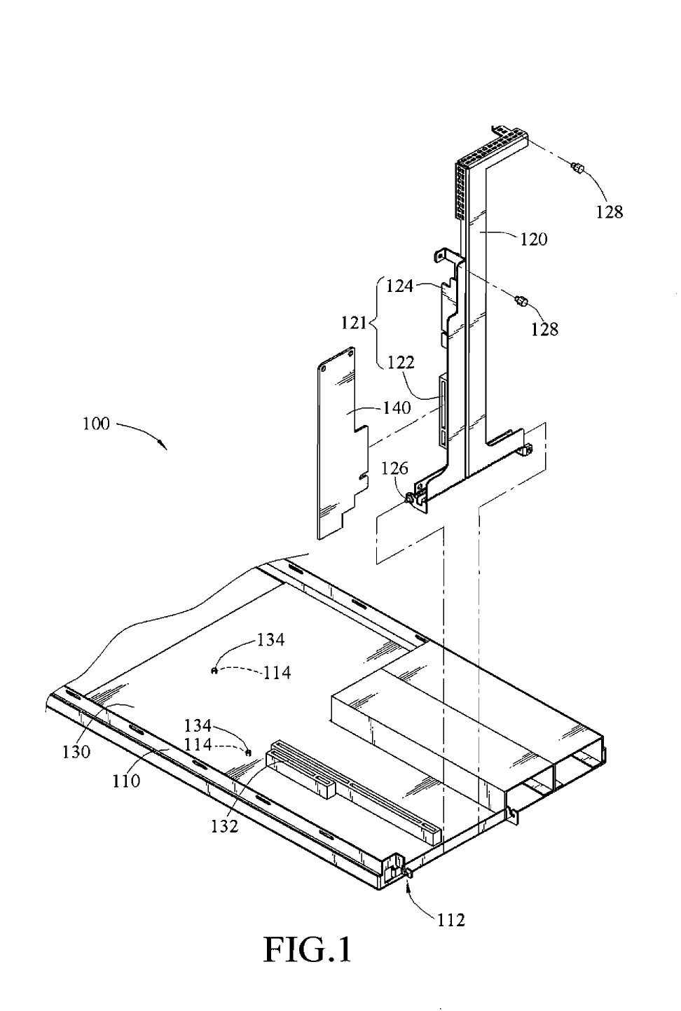

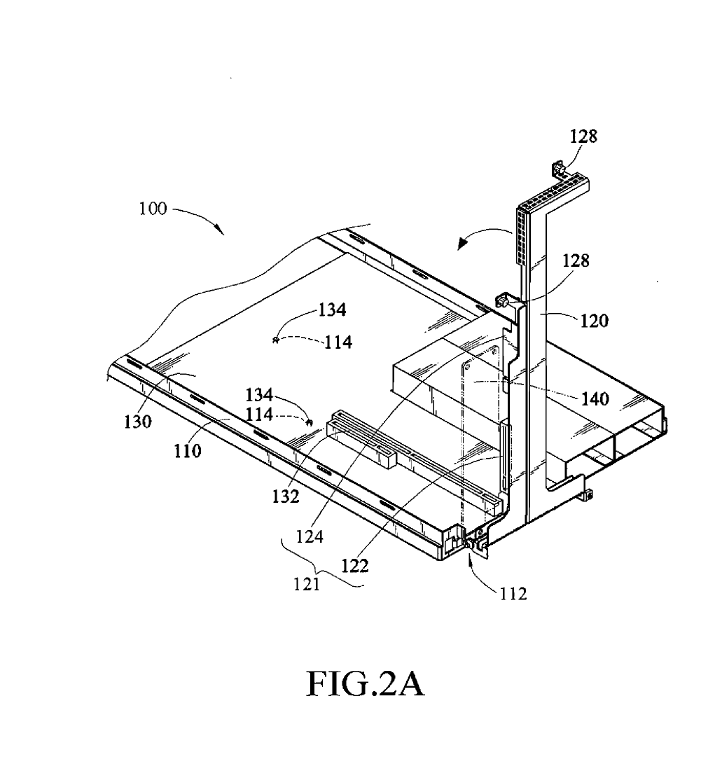

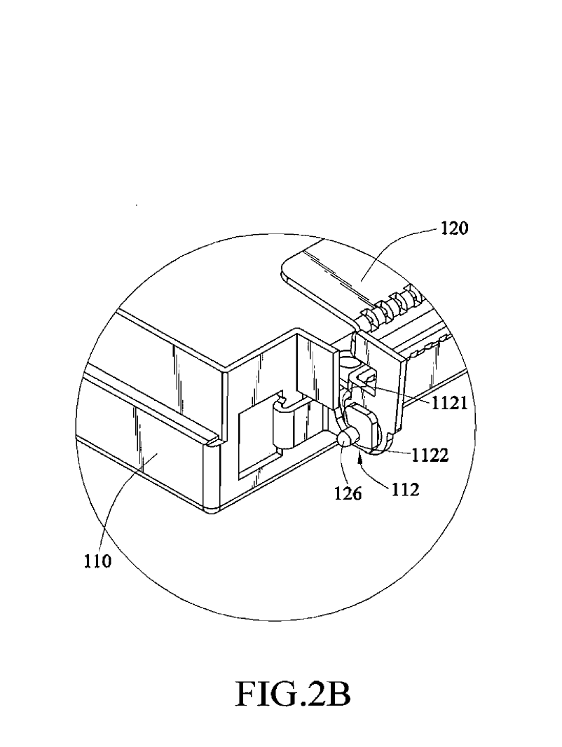

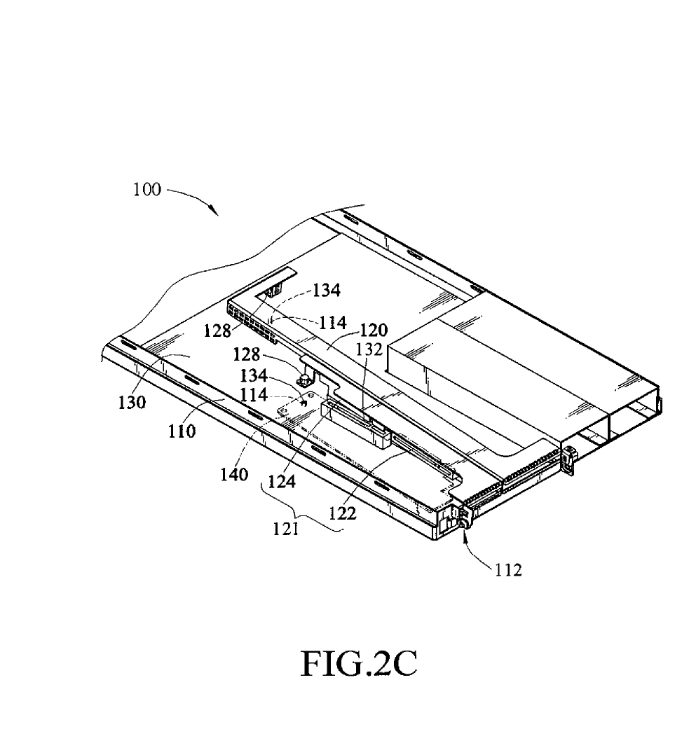

Referring to FIGS. 1, 2A, 2B, and 2C, a case 100 of an electronic device in a first embodiment is shown, for example, a case of 1U server computer. The case 100 of the electronic device includes at least one base 110, an cover (not shown), and an interface card retaining assembly.

Referring to FIG. 1, the electronic device includes at least one circuit board 130, such as a motherboard, disposed on an inner side of the base 110 and located within the case 100. The circuit board 130 has at least one expansion slot 132 for a functional expansion card to be inserted therein, so as to have functional expansion card be electrically connected to the interface card cradle 120. The functional expansion card can be a raiser card or an interface card. In this embodiment, the functional expansion card is a raiser card 121. A cover of the case 100 covers the base 110 to form an accommodating space, for accommodating the interface card retaining assembly and the circuit board 130. The base 110 has two pivoting portions 112 extended from the edge of the base 110.

Referring to FIGS. 1, 2A, and 2B, the interface card retaining assembly is disposed in the case 100, wherein the interface card retaining assembly includes an interface card cradle 120 and a raiser card 121. The interface card cradle 120 has two pivotal pins 126, respectively disposed on two side of the interface card cradle 120 and extending outward towards opposite directions. The pivotal pins 126 are monolithically formed on the interface card cradle 120, or embedded and fixed on the interface card cradle 120. The pivotal pins 126 are used to be inserted into the pivoting portion 112 of the base 110, such that the interface card cradle 120 is pivoted to the pivoting portion 112 of the base 110, and thereby being pivoted to the case 100. Therefore, the interface card cradle 120 swings relative to the case 100 and the base 110 to lean against the base 110 and the circuit board 130.

Referring to FIG. 1, the raiser card 121 is disposed on the interface card cradle 120. The raiser card 121 has an adapter slot 122 and a connector 124, in which the adapter slot 122 is provided for an interface card 140 to be inserted therein, thereby making the interface card 140 be electrically connected to the raiser card 121. When the interface card cradle 120 leans against the base 110 and the circuit board 130, the connector 124 of the raiser card 121 is inserted into the expansion slot 132 of the circuit board 130, so as to make the interface card 140 be electrically connected to the circuit board 130 through the raiser card 121.

Referring to FIG. 2B, in this embodiment, a slot 1122 is formed on the pivoting portion 112, which is curve-shaped. The slot 1122 has an opening 1121 formed on the edge of the pivoting portion 112. The pivotal pin 126 of the interface card cradle 120 slides into the slot 1122 through the opening 1121, slides and rotates within the slot 1122, thereby making the pivotal pin 126 be inserted into the pivoting portion 112 of the base 110. The shape of the slot 1122 provided by the present invention is not limited to the curve-shaped, but can be other shape, for example, a through hole and an oblique slot are formed on the pivoting portion 112.

Next, referring to FIG. 2C, when the interface card cradle 120 is pivoted to the base 110, a force is applied to the interface card cradle 120 along the arrow direction shown in FIG. 2A, so as to make the interface card cradle 120 to rotate and to be drawn close to the base 110. Once the interface card cradle 120 leans against the base 110, the connector 124 of the raiser card 121 is inserted into the expansion slot 132 of the circuit board 130.

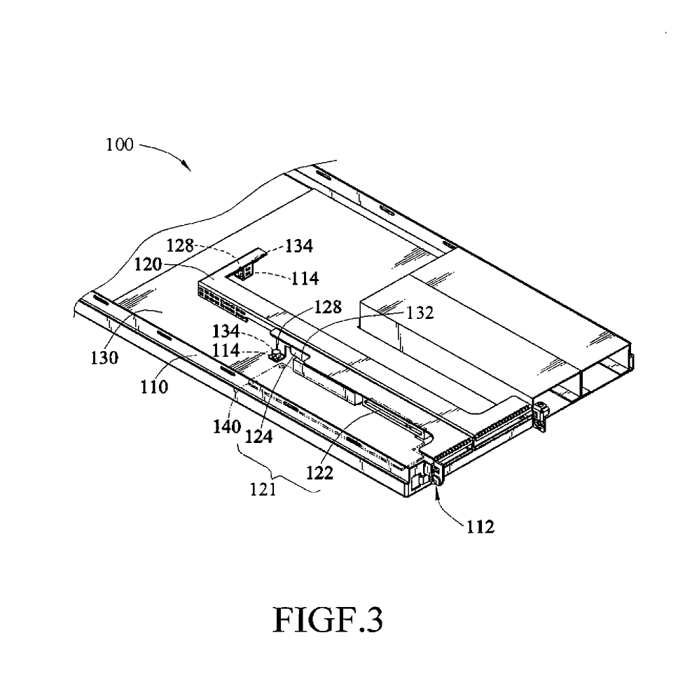

In addition, referring to FIGS. 1 and 3, the interface card retaining assembly of the case 100 of the electronic device in the present invention further has two fixing members 128, and the fixing members 128 pass through the interface card cradle 120. On the base 110, a fixing hole 114 is formed corresponding to each fixing member 128, and a through hole 134 is further formed on the circuit board 130 corresponding to each fixing hole 114. Therefore, when the interface card cradle 120 leans against the base 110, and after the connector 124 is inserted into the expansion slot 132, the fixing member 128 passing through the interface card cradle 120 further passes through the through hole 134 of the circuit board 130, and then is engaged into the fixing hole 114 of the base 110. Thus the interface card cradle 120 and the circuit board 130 are fixed to the base 110. In this embodiment, the fixing member 128 of the interface card retaining assembly is a thumb screw, and the fixing hole 114 on the base 110 is a screw hole. Therefore, the thumb screw is screwed and fixed into the screw hole to fix the interface card cradle 120 on the base 110.

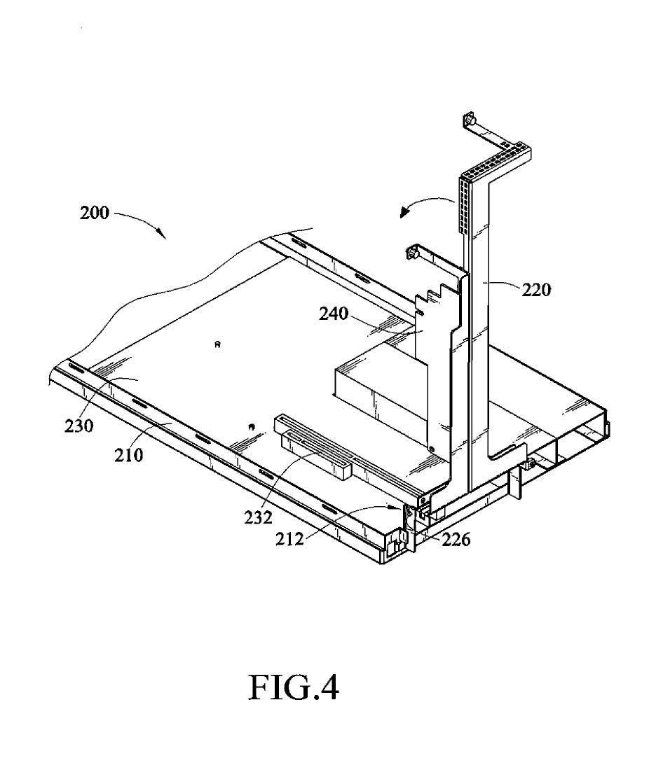

Referring to FIG. 4, case of an electronic device according to a second embodiment of the present invention is provided. The structure of the case 200 of the electronic device in the second embodiment of the present invention is approximately the same as that of the first embodiment. Similar to first embodiment, the pivotal pin 226 of the interface card cradle 220 is used to pivot the interface card cradle 220 to the pivoting portion 212 of the base 210. The difference there-between is that, in the second embodiment of the present invention, the functional expansion card is an interface card 240. The interface card 240 is fixed on the interface card cradle 220, and when the interface card cradle 220 leans against the base 210, the interface card 240 is directly inserted into the expansion slot 232 of the circuit board 230.

In the present invention, the pivotal pin and the curve-shaped slot are used to pivot the interface card cradle to the base, the interface card cradle and the base can rotate, and also slide relative to each other. After the interface card cradle has been pivoted to the base, it still has the freedom of moving to a small extent, which is helpful for the connector of the interface card retaining assembly to be aligned to and inserted into the expansion slot of the circuit board. In addition, before the thumb screw of the interface card retaining assembly is screwed into the screw hole of the base, the circuit board can be placed on the base without being fixed, which is also helpful for the connector of the interface card retaining assembly to be aligned to and inserted into the expansion slot of the circuit board because both the interface card cradle and the circuit board have the freedom of moving to a small extent.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A case of an electronic device, having a circuit board disposed therein, wherein the circuit board has at least one expansion slot for a functional expansion card to be inserted, the case comprising:
a base, having at least one pivoting portion, wherein the circuit board is disposed on the base; and
an interface card cradle, pivoted to the pivoting portion of the base, for swinging relative to the base, wherein the functional expansion card is mounted to the interface card cradle, and inserted into the expansion slot of the circuit board when the interface card cradle leans against the base.

2. The case of the electronic device as claimed in claim 1, wherein the pivoting portion extends from an edge of the base.

3. The case of the electronic device as claimed in claim 2, wherein a slot is formed in the pivoting portion, at least one pivotal pin is disposed on one side of the interface card cradle, and the pivotal pin slides and rotates within the slot.

4. The case of the electronic device as claimed in claim 3, wherein the slot of the pivoting portion has an opening formed on an edge of the pivoting portion, for the pivotal pin sliding into the slot through the opening.

5. The case of the electronic device as claimed in claim 3, wherein the slot is curve-shaped.

6. The case of the electronic device as claimed in claim 1, further comprising a fixing member, passing through the interface card cradle and fixed on the base, thereby fixing the interface card cradle on the base.

7. The case of the electronic device as claimed in claim 6, wherein the fixing member passes through the interface card cradle and passes through the circuit board, thereby fixing both the interface card cradle and the circuit board on the base.

8. An interface card retaining assembly, disposed in a case of an electronic device, wherein a circuit board having at least one expansion slot is disposed in the case, the interface card retaining assembly comprising:
an interface card cradle, pivoted to the case, for swinging relative to the case; and
a functional expansion card, mounted to the interface card cradle, wherein when the interface card cradle leans against the circuit board, the functional expansion card is inserted into the expansion slot of the circuit board to be electrically connected to the circuit board.

9. The interface card retaining assembly as claimed in claim 8, wherein the functional expansion card has an adapter slot for an interface card to be inserted therein, so as to have the interface card be electrically connected to the circuit board.

10. The interface card retaining assembly as claimed in claim 8, wherein the functional expansion card is an interface card.
